(19) United States
(12) Patent Application Publication
(10) Pub. No.: US 2008/0149933 A1
(43) Pub. Date: Jun. 26, 2008

(54) Display panel

(75) Inventors: Cheon-Jae Maeng, Suwon-si (KR); Yun-Seok Lee, Cheonan-si (KR); Young-Je Cho, Cheonan-si (KR); You-Hyun Jeong, Cheonan-si (KR); Byung-Hyun Kim, Asan-si (KR)

Correspondence Address: MACPHERSON KWOK CHEN & HEID LLP, 2033 GATEWAY PLACE, SUITE 400, SAN JOSE, CA, 95110, US

(73) Assignee: SAMSUNG ELECTRONICS CO., LTD.

(21) Appl. No.: 11/981,872

(22) Filed: Oct. 31, 2007

(30) Foreign Application Priority Data
Oct. 31, 2006 (KR) 2006-0106641

(51) Int. Cl. H01L 29/04

(52) U.S. Cl. 257/71; 257/E29.003

(57) ABSTRACT

A display panel includes a first substrate, a second substrate and a spacer. The first substrate includes a gate line, a data line crossing the gate line to define a pixel area, and a storage electrode formed in the pixel area. The second substrate is coupled with the first substrate and includes a first black matrix corresponding to the storage electrode. The spacer is interposed between the first and second substrates to allow the first and second substrates are spaced apart from each other. Thus, an aperture ratio of the display panel may be improved and a manufacturing cost of the display panel may be reduced.

### CROSS-REFERENCE TO RELATED APPLICATION

This application relies upon and claims priority to Korean Patent Application No. 2006-106641 filed on Oct. 31, 2006, the contents of which are herein incorporated by reference in its entirety.

### BACKGROUND OF THE INVENTION

1. Field of the Invention

The disclosure relates to a display panel. More particularly, the disclosure relates to a display panel capable of reducing a manufacturing cost thereof.

2. Description of the Related Art

In general, a liquid crystal display panel includes an array substrate, a color filter substrate coupled with the array substrate facing the color filter substrate, and a liquid crystal layer interposed between the array substrate and the color filter substrate. The array substrate includes gate lines and data lines crossing with the gate lines to define pixel areas. The liquid crystal display panel further includes a spacer disposed between the array substrate and the color filter substrate to maintain a uniform cell gap between the array substrate and the color filter substrate.

When an external impact is applied to a spacer formed in an area corresponding to a channel portion of the array substrate, the spacer is easily displaced from the channel portion due to a width and a step-difference of the channel portion, and the channel portion may be damaged by the spacer. Furthermore, align margin between the array substrate and the color filter substrate may be affected because the area of the channel portion is generally not sufficient.

Meanwhile, in forming the spacer in the pixel areas, the spacer has to have bigger thickness in order to maintain the cell gap than thickness of the spacer formed in the channel area. As a result, a manufacturing cost for the spacer and the liquid crystal display panel increases, and an aperture ratio of the liquid crystal display panel is reduced.

### SUMMARY OF THE INVENTION

An exemplary embodiment provides a display panel capable of reducing a manufacturing cost and improving an aperture ratio thereof.

In one aspect, a display panel includes a first substrate, a second substrate, and a spacer.

The first substrate includes a gate line, a data line crossing the gate line to define a pixel area, and a storage electrode formed in the pixel area. The second substrate is coupled with the first substrate while facing the first substrate, and includes a first black matrix formed thereon in correspondence with the storage electrode. The spacer is formed between the first black matrix and the storage electrode such that the first and second substrates are spaced apart from each other.

The first black matrix is smaller in width than the storage electrode when viewed in a plan view.

The spacer is a column spacer.

The storage electrode includes a first storage electrode formed at a center of the pixel area, and a second storage electrode facing the first storage electrode and being electrically connected to the thin film transistor.

The second substrate includes a common electrode provided with a opening formed therethrough. At least a portion of the opening is overlapped with the bottom area of the spacer.

According to the above, the spacer is formed corresponding to the area in which the storage electrode is formed, so that the aperture ratio of the display panel may not be reduced. Since the height of the spacer is reduced by the thickness of the first black matrix, the manufacturing cost of the display panel may be reduced.

### BRIEF DESCRIPTION OF THE DRAWINGS

The above and other advantages will become readily apparent by reference to the following detailed description when considered in conjunction with the accompanying drawings wherein:

FIG. 1 is a plan view showing an exemplary embodiment of a liquid crystal display panel;

FIG. 2A is a plan view showing a pixel of the liquid crystal display panel of FIG. 1;

FIG. 2B is a cross-sectional view taken along a line I-I′ of FIG. 2A;

FIG. 2C is a cross-sectional view taken along a line II-II′ of FIG. 2A;

FIG. 3A is a plan view showing a pixel electrode and a shielding part of FIG. 2A;

FIG. 3B is a plan view showing a first black matrix and a second black matrix of FIG. 2A;

FIG. 4A is a view illustrating a fabricating process of a spacer of FIG. 1;

FIG. 4B is a perspective view illustrating a coating process of a photoresist of FIG. 4A;

FIG. 4C is a cross-sectional view taken along a line III-III′ of FIG. 4B;

FIG. 4D is a sectional view showing a spacer fabricated by patterning a photoresist of FIG. 4A;

FIG. 5A is a plan view showing another exemplary embodiment of a liquid crystal display panel; and

FIG. 5B is a plan view showing a first black matrix and a second black matrix of FIG. 5A.

### DESCRIPTION OF THE EMBODIMENTS

Hereinafter, embodiments will be explained in detail with reference to the accompanying drawings. In the drawings, the thickness of layers, films, and regions are exaggerated for clarity. Like numerals refer to like elements throughout. It will be understood that when an element such as a layer, film, region, or substrate is referred to as being “on” another element, it can be directly on the other element or intervening elements may also be present.

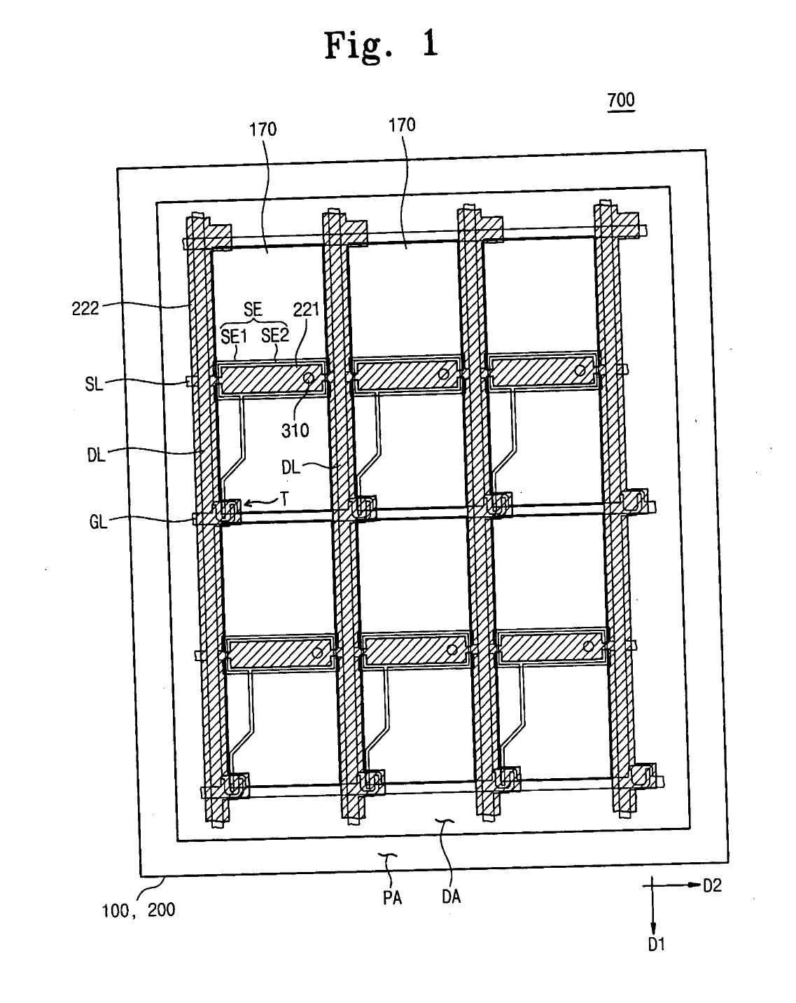

FIG. 1 is a plan view showing an exemplary embodiment of a liquid crystal display panel. The primary viewing direction is the primary direction in which a user views the images on the display panel. This primary viewing direction is perpendicular to the page in FIG. 1, e.g., perpendicular to image shown on the liquid crystal display panel. In FIG. 1, a liquid crystal display panel has been shown as an example of the display panel, but the display panel is not limited to the liquid crystal display panel.

Referring to FIG. 1, a liquid crystal display panel 700 includes an array substrate 100, a color filter substrate 200, and a spacer 310 disposed between the array substrate 100 and the color filter substrate 200.

The liquid crystal display panel 700 includes a display area DA in which an image is displayed and a peripheral area PA surrounding the display area DA. The array substrate 100 includes pixels arranged in the display area DA. Each of the pixels includes a data line DL, a gate line GL, a storage electrode SE, a thin film transistor T, and a pixel electrode 170. The gate line GL and the data line DL are insulted from each other and intersect each other to define pixel areas. The data line DL includes a plurality of lines extending in a first direction D1 on the array substrate 100, and the gate line GL includes a plurality of lines extending in a second direction D2 substantially perpendicular to the first direction D1.

The thin film transistor T is positioned at a corner of the pixel area and is electrically connected to the gate line GL and the data line DL. The pixel electrode 170 is formed in the pixel area and is electrically connected to the thin film transistor T.

The storage electrode SE is formed in the pixel area and includes a first storage electrode SE1 and a second storage electrode SE2 facing the first storage electrode SE1. In the present exemplary embodiment, the first storage electrode SE1 is positioned at a center portion of the pixel area. The second storage electrode SE2 is electrically connected to the thin film transistor T and faces the first storage electrode SE1.

The array substrate 100 further includes a storage line SL to electrically connect the first storage electrode SE1 and an adjacent first storage electrode. The storage line SL extends in a second direction D2 substantially parallel to the gate line GL and intersecting with the data line DL. The first storage electrode SE1 and the storage line SL are formed with the gate line GL, and the second storage electrode SE2 is formed with the data line DL.

The color filter substrate 200 is coupled with the array substrate 100 while facing the array substrate 100 and includes a first black matrix 221 and a second black matrix 222. The first black matrix 221 is formed on the color filter substrate 200 corresponding to the storage electrode SE such that the first black matrix 221 overlaps with the storage electrode SE when viewed in plan view, as shown in FIG. 1. When viewed in a plan view, the first black matrix 221 is smaller in width than the storage electrode SE. This is because an aperture ratio of the pixel area may be reduced when the first black matrix 221 is larger than the storage electrode SE.

The second black matrix 222 is formed on the color filter substrate 200 corresponding to the data line DL and the thin film transistor T such that the second black matrix 222 overlaps with the data line DL and the thin film transistor T when viewed in plan view, as shown in FIG. 1. By forming the second black matrix 222 to correspond to the data line DL and the thin film transistor T, the second black matrix 222 can block light which passes through the data line DL and the thin film transistor T. The second black matrix 222 is formed on the color filter substrate 200 corresponding to a non-effective display area of the array substrate 100. That is, the array substrate 100 is divided into an effective display area on which images are displayed and a non-effective display area on which images are not displayed. The non-effective display area in which the gate line GL, the data line DL and the thin film transistor T are formed does not transmit light therethrough, so that images are not displayed on the non-effective display area. In the present exemplary embodiment, the portions of the second black matrix 222 formed in areas in which the gate line GL is formed has not been shown, but the second black matrix 222 may also be formed in the area in which the gate line GL is formed. As viewed in the plan view shown in FIG. 1, the second black matrix 222 is larger in size than the data line DL and the thin film transistor T when considering a diffusivity of the light.

The spacer 310 is formed between the first black matrix 221 and the storage electrode SE to maintain the array substrate 100 spaced apart from the color filter substrate 200. Since the spacer 310 is formed in the area in which the storage electrode SE is formed, the aperture ratio of the liquid crystal display panel 700 is not reduced. Also, the spacer 310 has a height reduced by a thickness of the first black matrix 221, so that an amount of a material used to form the spacer 310 may be reduced. For instance, a photoresist may be used to form the spacer 310 when the spacer 310 is a column spacer, and a coated amount of the photoresist is reduced due to the first black matrix 221, thereby reducing the manufacturing cost of the spacer 310.

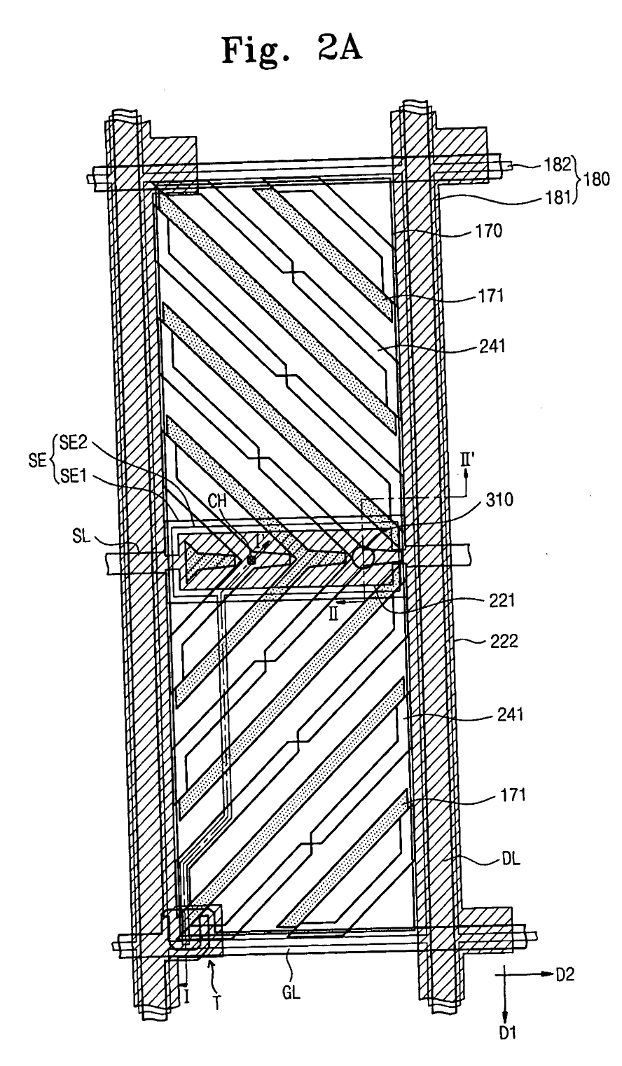

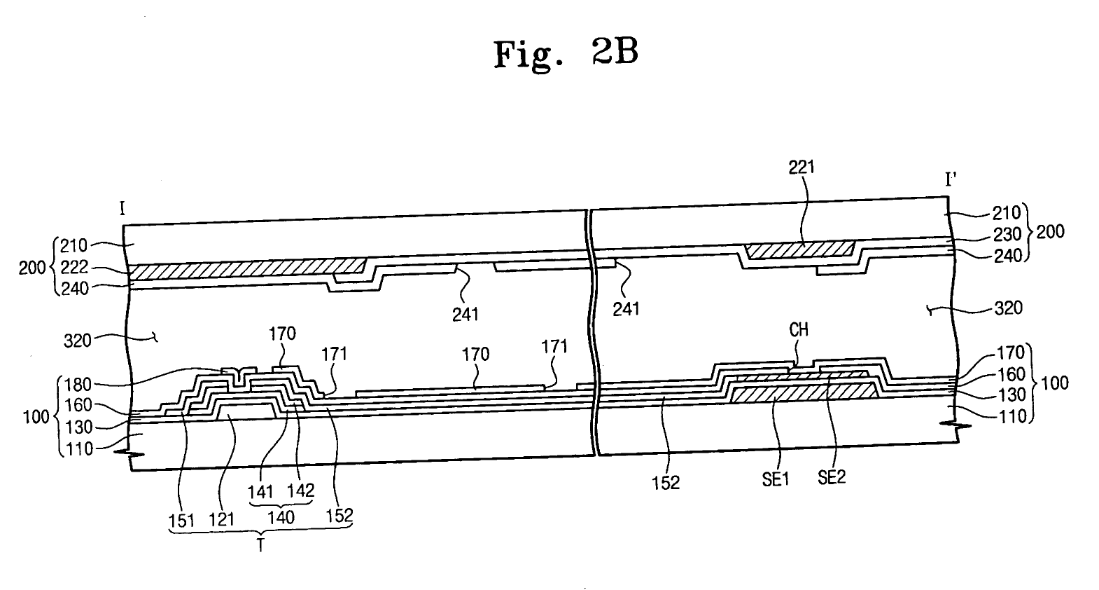

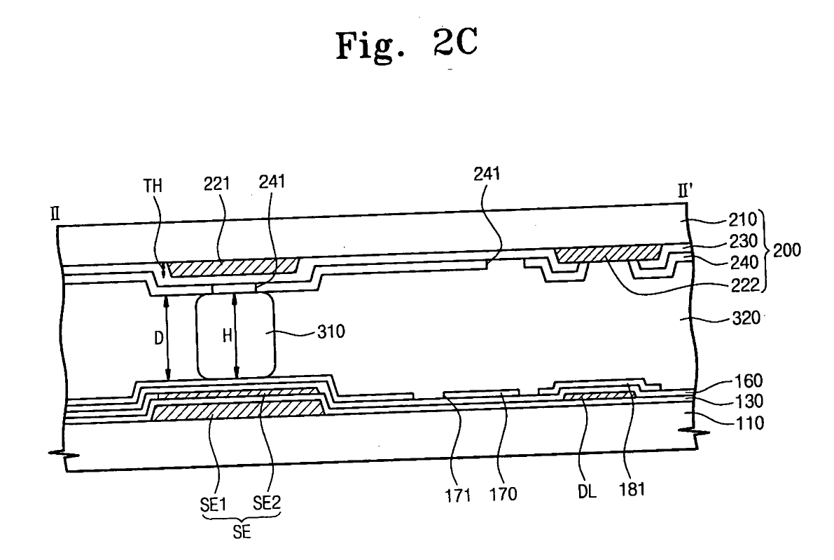

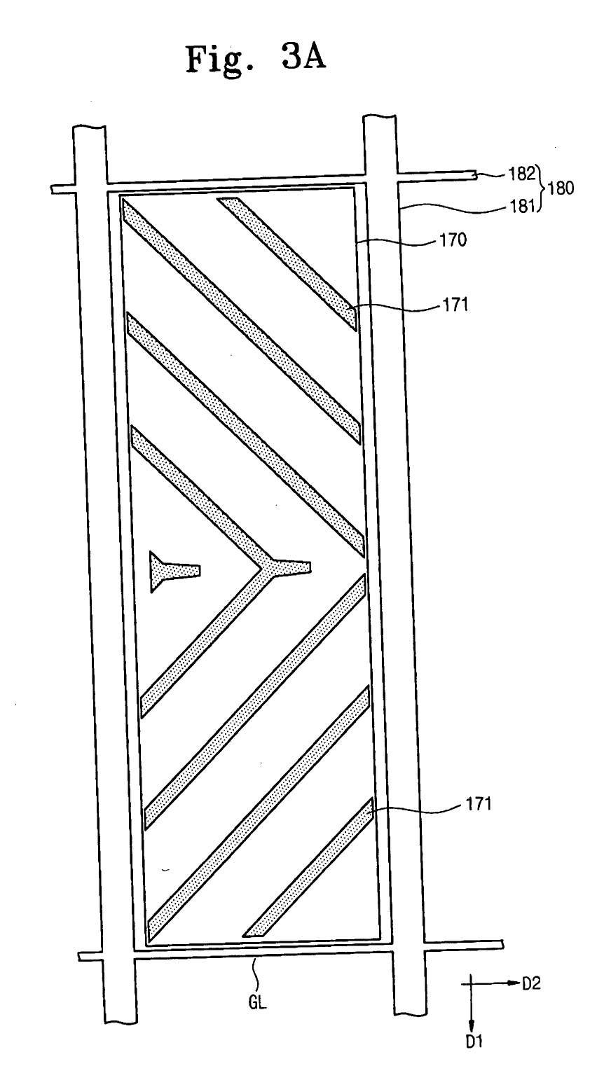

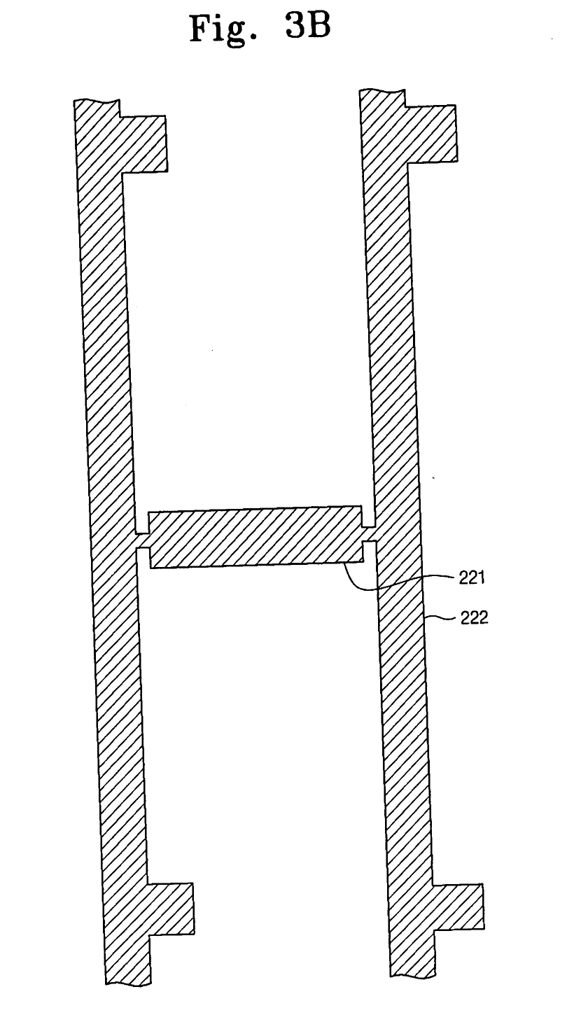

FIG. 2A is a plan view showing a pixel of the liquid crystal display panel of FIG. 1, FIG. 2B is a cross-sectional view taken along a line I-I′ of FIG. 2A, FIG. 2C is a cross-sectional view taken along a line II-II′ of FIG. 2A, FIG. 3A is a plan view showing a pixel electrode and a shielding part of FIG. 2A, and FIG. 3B is a plan view showing a first black matrix and a second black matrix of FIG. 2A. In FIGS. 2A to 3B, each of the pixels have the same structure, and thus only one pixel will be described as a representative example.

Referring to FIGS. 2A to 2C, the liquid crystal display panel 700 includes the array substrate 100, the color filter substrate 200, and the spacer 310. The liquid crystal display panel 700 further includes a liquid crystal layer 320 interposed between the array substrate 100 and the color filter substrate 200 to adjust the transmittance of the light.

The array substrate 100 includes a first base substrate 110, the gate line GL formed on the first base substrate 110 and extended in the second direction D2, and a gate insulating layer 130 covering the first storage electrode SE1. The gate insulating layer 130 is formed by depositing an inorganic material (e.g. silicon nitride) on the first base substrate 110.

The thin film transistor T is electrically connected to the pixel electrode 170 to apply a pixel voltage to the pixel electrode 170 or to block the pixel voltage. The thin film transistor T includes a gate electrode 121 branched from the gate line GL, a semiconductor pattern 140 formed above the gate electrode 121, a source electrode 151 formed on the semiconductor pattern 140 and branched from the data line DL, and a drain electrode 152 spaced apart from the source electrode 151. The semiconductor pattern 140 includes an active pattern 141 in which a channel of the thin film transistor T is formed and an ohmic contact pattern 142 formed under the source and drain electrodes 151 and 152.

The second storage electrode SE2 extends from the drain electrode 152 and in a direction opposite to the first storage electrode SE1. The first storage electrode SE1, the second storage electrode SE2, and the gate insulating layer 130 disposed between the first and second storage electrodes SE1 and SE2 define a storage capacitor.

The array substrate 100 further includes a protective layer 160 that covers the data line DL, the second storage electrode SE2, and the thin film transistor T. The protective layer 160 is formed using an inorganic material. The protective layer 160 is partially removed to form a contact hole CH through which the second storage electrode SE2 is exposed, and the pixel electrode 170 is formed on the protective layer 160. The pixel electrode 170 is electrically connected to the second storage electrode SE2 through the contact hole. The pixel electrode 170 includes a transparent conductive material (e.g. indium tin oxide or indium zinc oxide) and receives the pixel voltage.

Referring to FIGS. 2A and 3A, the pixel electrode 170 is patterned to divide the pixel area into a plurality of domains in which liquid crystal molecules are aligned in different directions. In other words, the pixel electrode 170 is provided with first openings 171 formed therethrough. The first openings 171 are inclined at a predetermined angle with respect to an imaginary line crossing the center of the pixel area along the second direction D2, and symmetrical with each other with respect to the imaginary line. The first openings 171 divide the pixel electrode 170 into the plurality of domains. Further, some of the first openings 171 that are formed at the center of the pixel area may be further extended along the imaginary line.

Referring to FIGS. 2A to 3A, the array substrate 100 further includes a shielding part 180 formed on the protective layer 160. The shielding part 180 includes a first shielding electrode 181 and a second shielding electrode 182 and is spaced apart from the pixel electrode 170, so that the shielding part 180 is insulated from the pixel electrode 170. The first shielding electrode 181 is formed in an area corresponding to the data line DL and extends in a direction substantially parallel to the data line DL, and the second shielding electrode 182 is formed in an area corresponding to the gate line GL and extends in a direction substantially parallel to the gate line GL.

The color filter substrate 200 includes a second base substrate 210 on which the first and second black matrices 221 and 222 are formed, a color layer 230, and a common electrode 240.

The color layer 230 and the first and second black matrices 221 and 222 are formed on the second base substrate 210. The color layer 230 is formed on the second base substrate 210 corresponding to the pixel areas. The color layer 230 includes red, green and blue color pixels arranged in a one-to-one correspondence with the pixel areas. The second black matrix 222 individually surrounds each of the color pixels.

As shown in FIGS. 2A and 3B, when viewed in a plan view, the first black matrix 221 is connected to the second black matrix 222 adjacent to the first black matrix 221. That is, the first black matrix 221 may be integrally formed with the second black matrix 222, so that the first black matrix 221 is connected with the second black matrix 222 when viewed in a plan view.

Referring to FIG. 2C, the color layer 230 is formed on the first black matrix 221 in an area in which the storage electrode SE is formed, and the spacer 310 is interposed between the array substrate 100 and the color filter substrate 200 in correspondence with the first black matrix 221. Accordingly, the spacer 310 is covered by the first black matrix 221 when viewed in plan view of FIG. 2A (which corresponds to the viewing direction when the display is in use). The spacer 310 has a height H smaller than or equal to a gap between the array substrate 100 and the color filter substrate 200 in the area in which the storage electrode SE is formed. Since the spacer 310 is interposed between the array substrate 100 and the color filter substrate 200 in the area in which the first black matrix 221 is formed, the height H of the spacer 310 is reduced by the thickness of the first black matrix 221, as shown in FIG. 2C.

Also, since the spacer 310 makes contact with the array substrate 100 in the area in which the storage electrode SE is formed, an area where the spacer 310 and the array substrate 100 may make contact with each other can be larger and flatter than that when the spacer 310 makes contact with the array substrate 100 in the area in which the channel of the thin film transistor T is formed. Therefore, the spacer 310 may not be easily displaced and the channel portion may not be damaged by the spacer 310. Furthermore, align margin between the array substrate 100 and the color filter substrate 100 may not be affected.

The array substrate 100 and the color filter substrate 200 are spaced apart from each other by the first black matrix 221 and the spacer 310 interposed therebetween. The spacer 310 is formed on either the array substrate 100 or the color filter substrate 200.

The common electrode 240 is formed on the second black matrix 222 and the color layer 230. The common electrode 240 faces the pixel electrode 170 with the liquid crystal layer 320 interposed therebetween. The common electrode 240 includes the transparent conductive material (e.g. ITO or IZO) and is provided with second openings 241 formed therethrough in order to define the domains. When viewed in a plan view, the second openings 241 are positioned between the first openings 171, respectively. That is, the first and second openings 171 and 241 are alternately arranged when viewed in a plan view. The second openings 241 are inclined with respect to the imaginary line, and symmetrical with each other with respect to the imaginary line. As shown in FIG. 2A, the second openings 241 may be partially removed at the center of the pixel area along the imaginary line, or extended in substantially parallel to the gate and data lines GL and DL in adjacent areas to the gate and data lines GL and DL, respectively. Further, at least one of the second openings 241 may be overlapped with the bottom area of the spacer 310.

As described above, each of the pixel areas of the liquid crystal display panel 700 is divided into the domains, thereby improving the visibility of the liquid crystal display panel 700.

When operating the liquid crystal display panel 700, a gate signal is transmitted through the gate line GL, and a data signal corresponding to image information is transmitted through the data line DL. When the thin film transistor T is turned on in response to the gate signal, the pixel voltage corresponding to the data signal is applied to the pixel electrode 170, and simultaneously the common voltage is applied to the common electrode 240. As a result, an electric field is formed between the array substrate 100 and the color filter substrate 200. When the electric field is formed between the pixel electrode 170 and the common electrode 240, arrangements of the liquid crystal molecules of the liquid crystal layer 320 are converted by the electric field. Thus, the transmittance of the light incident from an exterior is adjusted by the arrangements of the liquid crystal molecules, so that the image corresponding to the transmittance of the light is displayed on the display area DA.

The liquid crystal molecules of the liquid crystal layer 320 are formed between the array substrate 100 and the color filter substrate 200 using a vacuum injection method or a dropping method. In the present exemplary embodiment, the amount of the liquid crystal molecules are reduced by a volume of the first black matrix 221 formed in the liquid crystal display 700, so that the manufacturing cost of the liquid crystal display panel 700 may be reduced.

The liquid crystal display panel 700 further includes a sealant (not shown) interposed between the array substrate 100 and the color filter substrate 200 to couple the array substrate 100 with the color filter substrate 200. The sealant is formed along the edges of the array substrate 100 or the color filter substrate 200. The sealant seals the display panel 700 to prevent the liquid crystal molecules from leaking out of the liquid crystal display panel 700.

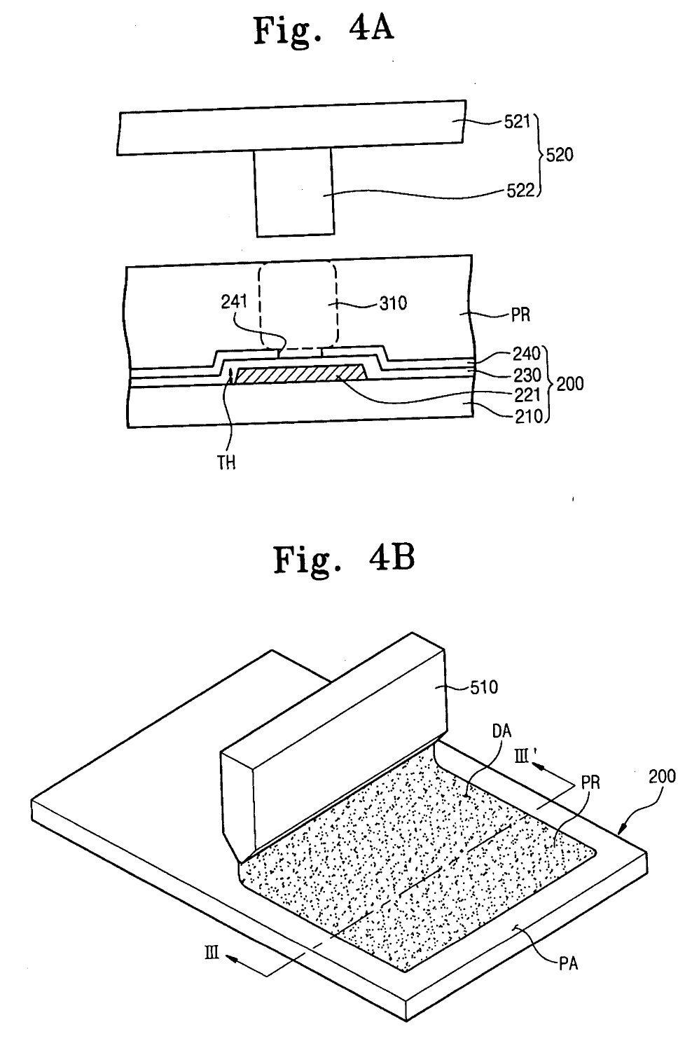

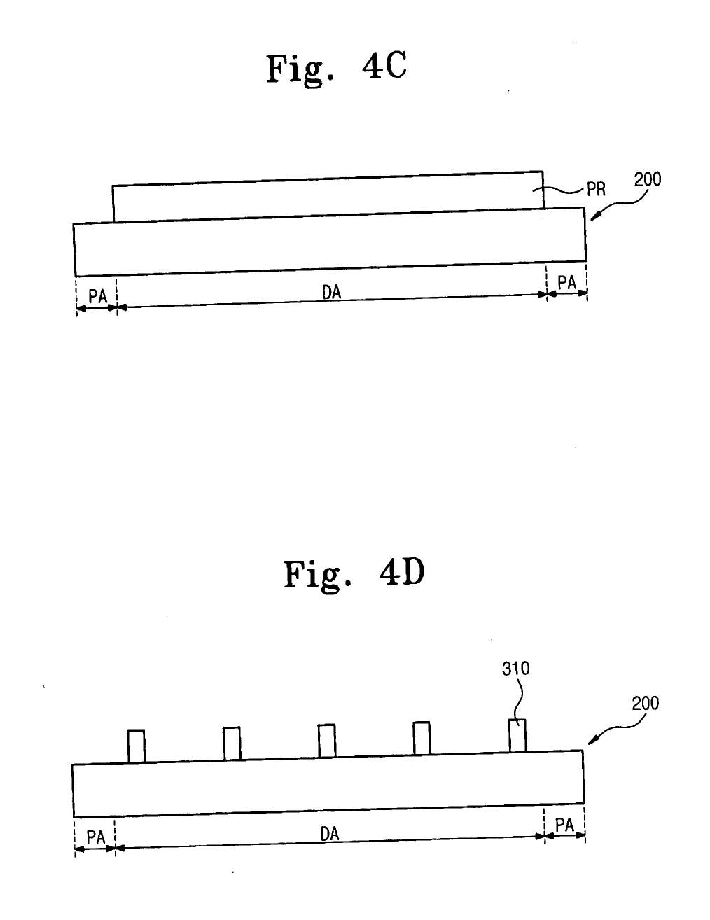

FIG. 4A is a view illustrating a fabricating process of a spacer of FIG. 1, FIG. 4B is a perspective view illustrating a coating process of a photoresist of FIG. 4A, FIG. 4C is a cross-sectional view taken along a line III-III′ of FIG. 4B, and FIG. 4D is a sectional view showing a spacer fabricated by patterning a photoresist of FIG. 4A.

In the present exemplary embodiment, a process of fabricating the spacer using the photoresist will be described. Variations of the process will be understood to be with the scope and teachings described herein. Further, the spacer may be formed on either the array substrate or the color filter substrate, however the spacer formed on the color filter substrate will be described as a representative example. In order to conveniently explain the process, the color filter substrate has been omitted in FIGS. 4B to 4D.

Referring to FIG. 4A, the first black matrix 221 is formed on the color filter substrate 200 corresponding to the area in which the storage electrode SE is formed. It is desirable that the first black matrix 221 is formed from the same layer of material as the second black matrix 222 (not shown in FIG. 4A). The color layer 230 is formed on the color filter substrate 200 corresponding to the pixel areas and disposed above the first black matrix 221. The first and second black matrices 221 and 222 and the color layer 230 may be formed using a photolithography process.

The transparent conductive layer is formed on the color layer 230 and the second black matrix 222 and patterned to form the common electrode 240. The transparent conductive layer may be ITO or IZO, and a photo-etch process is applied to the process of patterning the transparent conductive layer.

The spacer 310 is formed on the color filter substrate 200 corresponding to the area in which the first black matrix 221 is formed, such that the spacer 310 overlaps the color filter substrate 200 when viewed from the primary viewing direction. The process of forming the spacer 310 is as follows.

Referring to FIGS. 4B and 4C, the photoresist PR is uniformly coated over the display area DA on which the spacer 310 is formed using a spray unit 510 containing the photoresist PR therein.

Since the height of the spacer 310 is reduced by the thickness TH of the first black matrix 221, the amount of the photoresist PR needed to form the spacer 310 is also reduced, so that the manufacturing cost may be reduced. The coating amount of the photoresist PR is adjusted by a spray speed of the photoresist PR from the spray unit 510.

As an example, in case that the liquid crystal display panel 700 has a size of 46 inches, the spray speed of the photoresist PR is about 4400 μl/s, and the spray speed of forming the spacer on the conventional liquid crystal display panel having the same size of 46 inches is about 5400 μl/s. Thus, the coated amount of the photoresist PR is reduced by about 18.5 percents in comparison with the conventional liquid crystal display panel. Consequently, the manufacturing cost may be reduced.

When the photoresist PR is patterned through exposure and development processes, the spacer 310 is formed on the color filter substrate 200 corresponding to the area in which the storage electrode SE is formed as shown in FIG. 4D.

Referring to FIG. 4A again, the photo mask 520 is disposed above the color filter substrate 200 on which the photoresist PR is coated. The photo mask 520 includes a quartz substrate 521 through which the light from the exterior passes and a spacer pattern 522 formed on the quartz substrate 521. The spacer pattern 522 has a shape corresponding to the spacer 310 and includes is successively formed on the quartz substrate 521 while spacing apart from adjacent spacer pattern. The spacer pattern 522 includes chromium that blocks the light.

The light is irradiated onto the color filter substrate 200 from above the photo mask 520 to expose the photoresist PR. The portion of the photoresist PR facing the spacer pattern 522 does not react with the light since the light is blocked by the spacer pattern 522. Thus, the photoresist PR corresponding to the spacer pattern 522 is not removed during the development process and is maintained on the color filter substrate 200 after the development process, so that the spacer 310 is formed.

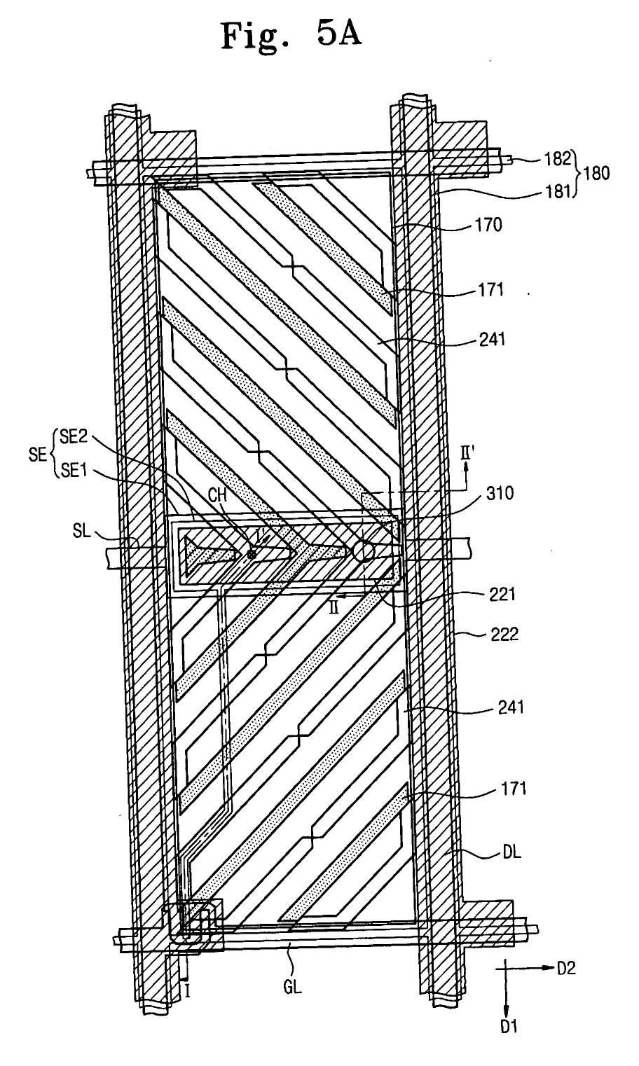

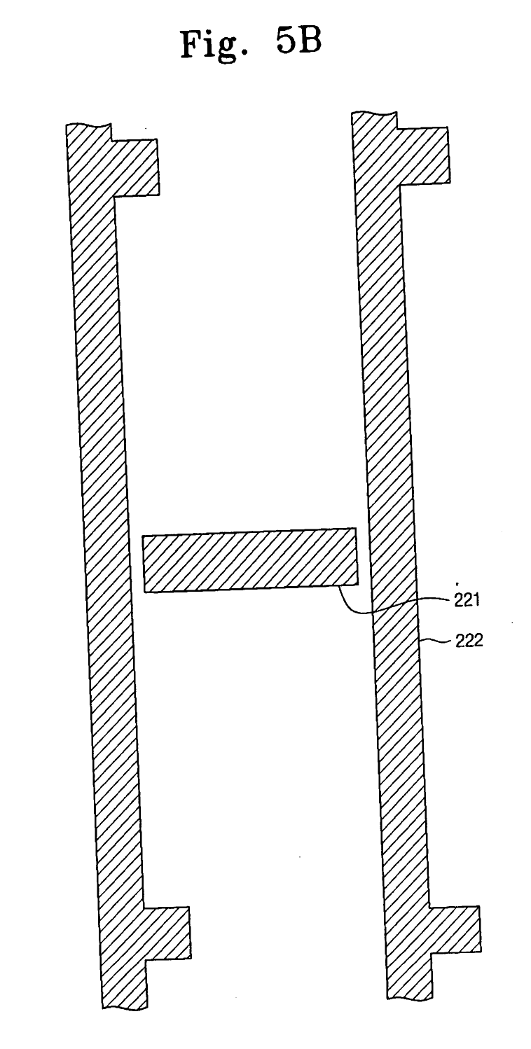

FIG. 5A is a plan view showing another exemplary embodiment of a liquid crystal display panel according to the present invention, and FIG. 5B is a plan view showing a first black matrix and a second black matrix of FIG. 5A. In FIGS. 5A and 5B, the same reference numerals denote the same elements in FIG. 2A, and thus the detailed descriptions of the same elements will be omitted.

Referring to FIGS. 5A and 5B, the first black matrix 221 is formed on the second base substrate 210 corresponding to the area in which the storage electrode SE is formed. The second black matrix 222 is also formed on the second base substrate 210 corresponding to the area in which the data line DL and the thin film transistor T are formed. When viewed in a plan view, the first black matrix 221 is spaced apart from the second black matrix 222. Thus, the first black matrix 221 is spaced apart from the data line DL when viewed in a plan view.

According to the above, the spacer is formed corresponding to the area in which the storage electrode is formed, so that the aperture ratio of the display panel may not be reduced. Since the height of the spacer is reduced by the thickness of the first black matrix, the manufacturing cost of the spacer may be reduced. Further, the amount of the liquid crystal interposed between the array substrate and the color filter substrate is reduced, thereby reducing the manufacturing cost of the display panel.

Although exemplary embodiments have been described, it is understood that various changes and modifications can be made by one ordinary skilled in the art within the spirit and scope of the claimed subject matter.

What is claimed is:

1. A display panel comprising:
a first substrate comprising a gate line, a data line crossing the gate line to define a pixel area, and a storage electrode formed in the pixel area;
a second substrate coupled with the first substrate while facing the first substrate, the second substrate comprising a first black matrix formed thereon in correspondence with the storage electrode; and
a spacer formed between the first black matrix and the storage electrode such that the first and second substrates are spaced apart from each other.

2. The display panel of claim 1, wherein the first black matrix is smaller in width than the storage electrode when viewed in a plan view.

3. The display panel of claim 1, wherein the spacer is a column spacer.

4. The display panel of claim 1, wherein the storage electrode comprises:
a first storage electrode formed at a center of the pixel area; and
a second storage electrode facing the first storage electrode and being electrically connected to the thin film transistor.

5. The display panel of claim 1, wherein the second substrate comprises:
a common electrode provided with a opening formed therethrough,
wherein at least a portion of the opening is overlapped with the bottom area of the spacer.
